(19) United States
(12) Patent Application Publication
(10) Pub. No.: US 2008/0038930 A1
(43) Pub. Date: Feb. 14, 2008

(54) Method of ashing an object and apparatus for performing the same

(76) Inventors: Jae-Kyung Park, Hwaseong-si (KR); Won-Soon Lee, Suwon-si (KR); Young-Kyou Park, Seoul (KR); No-Hyun Huh, Yongin-si (KR); Yong-Ho Park, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/808,523

(22) Filed: Jun. 11, 2007

(30) Foreign Application Priority Data
Aug. 14, 2006 (KR) 2006-76526

(51) Int. Cl. H01L 21/3065; C23F 1/00

(52) U.S. Cl. 438/726; 156/345.35; 156/345.36; 438/710; 257/E21.218

(57) ABSTRACT

Example embodiments relate to a method and an apparatus of ashing an object. The method may include converting a first reaction fluid into plasma, reacting the plasma with a second reaction fluid to generate radicals, and ashing the object using the radicals and the plasma.

### BACKGROUND OF THE INVENTION

1. Field of the Invention

Example embodiments relate to a method of ashing an object, and an apparatus for performing the same. More particularly, example embodiments relate to a method of ashing a photoresist pattern on a semiconductor substrate, and an apparatus for performing the method.

2. Description of the Related Art

Recently, as information technologies have been rapidly developed and information media, e.g., a computer, have been widely used, semiconductor devices have been highly integrated to meet the requirements of cutting-edge technologies. These semiconductor devices may be provided with rapid processing speeds and massive storage capacities. Therefore, the semiconductor devices have been developed in order to improve integration, reliability and responsive speed.

A semiconductor device may generally be manufactured by a deposition process, an etching process, an ion implantation process, a polishing process, or a cleaning process. In particular, the etching process may be a wet etching process or a dry etching process.

Further, in the etching process, an etching mask may be required to selectively etch a layer on a semiconductor substrate. Similarly, in the ion implantation process, an ion implantation mask may be required to selectively implant impurities into a semiconductor substrate. The masks employed in these processes may include a photoresist pattern formed by forming a photoresist film on the semiconductor substrate, exposing the photoresist film, and developing the photoresist film.

After completing the etching process and the ion implantation process, an ashing process may be carried out to remove the photoresist pattern. The photoresist pattern where the ion implantation process is not performed may be removed using oxygen plasma that may be generated from an oxygen gas. However, a photoresist pattern where the ion implantation process is performed may be partially hardened. As a result, the oxygen plasma may not remove the hardened photoresist pattern. Due to the formation of hardened photoresist pattern, a rifluoromethane (CHF₃) gas and then oxygen gas may be used to remove the hardened photoresist pattern.

Accordingly, in the conventional ashing method, all of the gases, e.g., oxygen gas, nitrogen gas and CHF₃ gas, may be converted into the plasma. Thus, the plasma may be formed as a fluorine plasma. Because the fluorine plasma may have a high etching selectivity with respect to an underlying layer beneath the photoresist pattern, e.g., a polysilicon layer, the fluorine plasma may partially remove the polysilicon layer as well as the hardened photoresist pattern, thereby reducing a thickness of the polysilicon layer. As a result, the polysilicon layer having a thin thickness may deteriorate electrical reliability of a semiconductor device.

### SUMMARY OF THE INVENTION

Example embodiments are therefore directed to a method of ashing an object, which substantially overcome one or more of the problems due to the limitations and disadvantages of the related art.

It is therefore a feature of the example embodiments to provide a method of ashing a photoresist pattern that may be capable of suppressing the removal of an underlying layer beneath the photoresist pattern.

At least one of the above and other features of example embodiments may provide a method of ashing an object. The method may include converting a first reaction fluid into plasma, reacting the plasma with a second reaction fluid to generate radicals, and ashing the object using the radicals and the plasma.

At least one of the above and other features of example embodiments may provide an apparatus for ashing an object. The apparatus may include an ashing chamber that may receive the object, a plasma generator connected to the ashing chamber to convert a first reaction gas into plasma, and a fluid line that may supply a second reaction gas into the ashing chamber. The second reaction gas may be reacted with the plasma in the ashing chamber to generate radicals.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of an ashing apparatus in accordance with an example embodiment;

FIG. 2 illustrates a cross-sectional view of an ashing apparatus in accordance with another example embodiment;

FIG. 3 illustrates a cross-sectional view of an ashing apparatus in accordance with another example embodiment; and

FIG. 4 illustrates a flow chart of a method of ashing a photoresist pattern using the apparatus in FIG. 1 in accordance with an example embodiment.

### DETAILED DESCRIPTION OF THE INVENTION

Korean Patent Application No. 2006-76526 filed on Aug. 14, 2006, in the Korean Intellectual Property Office, and entitled: “Method of Ashing an Object and Apparatus for Performing the Same,” is incorporated by reference herein in its entirety.

Example embodiments will now be described more fully hereinafter with reference to the accompanying drawings. The invention may, however, be embodied in different forms and should not be construed as limited to the embodiments set forth herein. Rather, these example embodiments are provided so that this disclosure will be thorough and complete, and will fully convey the scope of the invention to those skilled in the art.

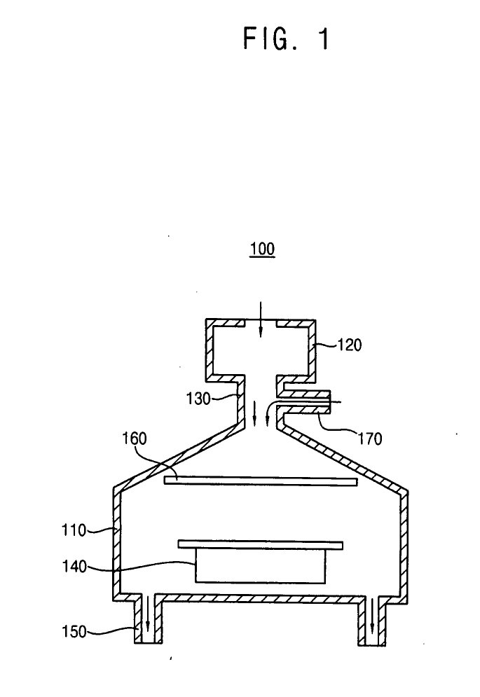

FIG. 1 illustrates a cross-sectional view of an ashing apparatus in accordance with an example embodiment.

Referring to FIG. 1, an ashing apparatus 100 in accordance with this example embodiment may include an ashing chamber 110, a plasma generator 120, an applicator 130, a chuck 140, an exhaust line 150, a baffle 160 and a gas line 170.

The chuck 140 may be positioned at a lower portion of the ashing chamber 110. An object to be ashed, such as a semiconductor substrate over which a photoresist pattern may be formed, may be placed on the chuck 140. The photoresist pattern may be formed on a polysilicon layer, for example, on the semiconductor substrate. The photoresist pattern may be used for patterning the polysilicon layer. In an example embodiment, an ion implantation process may be carried out on the photoresist pattern so that the photoresist pattern may be is partially hardened.

The plasma generator 120 may be arranged over the ashing chamber 110. The plasma generator 120 may be connected to an upper face of the ashing chamber 110 via the applicator 130. A first reaction gas may be introduced into the plasma generator 120. The plasma generator 120 may convert the first reaction gas into plasma using a microwave, for example. Thus, the plasma generator 120 may include a microwave generator and/or a remote plasma generator (RPG). It should be appreciated that other apparatuses, devices and/or elements may be used to generate the plasma.

Examples of the first reaction gas for removing the hardened photoresist pattern may include at least one of an oxygen gas and/or a nitrogen gas. It should be appreciated that other reaction gases may be employed besides the oxygen and nitrogen gases. The plasma generator 120 may covert the oxygen gas into oxygen plasma. The oxygen plasma may be chemically reacted with the hardened photoresist pattern to remove the hardened photoresist pattern from the semiconductor substrate. Further, the plasma generator 120 may convert the nitrogen gas into nitrogen plasma. The nitrogen plasma may increase a removal rate of the photoresist pattern using the oxygen plasma.

The baffle 160 may be positioned at an upper portion of the ashing chamber 110. Thus, the baffle 160 may be located over the chuck 140. However, one skilled in the art should appreciate that the baffle 160 may be located in other regions of the chamber 110. The baffle 160 may uniformly distribute the plasma onto the semiconductor substrate, and the baffle 160 may have a plurality of holes (not shown) for uniformly spraying the plasma.

However, the hardened photoresist pattern may not be completely removed using only the oxygen plasma. Therefore, a second reaction gas may be introduced into the ashing chamber 110 so as to completely remove any remaining hardened photoresist pattern. Examples of the second reaction gas may include at least one of a halogen gas, e.g., a rifluoromethane (CHF₃) gas, a chlorine (Cl₂) gas, a nitrogen trifluoride (NF₃) gas, and/or a hydrogen bromide (HBr) gas. It should be appreciated that other reaction gases may be employed besides the ones mentioned above. In this example embodiment, a fluorine gas, e.g., CHF₃ gas, may be used as the second reaction gas.

The ashing apparatus 100 may include the additional gas line 170 for supplying the second reaction gas into the ashing chamber 110. In an example embodiment, the gas line 170 may be connected to the applicator 130 (e.g., below the plasma generator 120). That is, the plasma converted from the first reaction gas in the plasma generator 120 may be introduced into the ashing chamber 110 while the second reaction gas having a gaseous state may be directly introduced into the ashing chamber 110. As a result, the second reaction gas may not be converted into plasma.

Accordingly, the oxygen plasma and the fluorine gas may be chemically reacted with each other to generate fluorine radicals, for example. The oxygen plasma and the fluorine radicals may be introduced into the ashing chamber 110 to remove the hardened photoresist pattern. The fluorine radicals, which may not be converted into plasma, may have a low etching selectivity with respect to the polysilicon layer compared to that of the plasma. Thus, the fluorine radicals may remove only the hardened photoresist pattern, and not the polysilicon layer.

By-products generated in the ashing process may then be exhausted from the ashing chamber 110 through the exhaust line 150, which may be connected to a lower face of the ashing chamber 110. It should be appreciated that the exhaust line 150 may also be located in other regions of the chamber 110, for example, sidewalls of the ashing chamber 110. It should further be appreciated that there may be a plurality of exhaust lines 150.

Although the above example embodiments described the photoresist pattern on the semiconductor substrate as an object, it should be appreciated by one skilled in the art that the ashing apparatus 100 may also be applied to a semiconductor substrate on which a nitride spacer, a metal contact, and/or a metal wiring, may be formed. That is, the ashing apparatus 100 may be applied to a process for removing, for example, but not limited to, a nitride in the nitride spacer, a process for removing metal polymers that remains after completing a formation of the metal contact and/or the metal wiring. It should be appreciated that other processes may be employed besides the ones mentioned above.

In accordance with the above example embodiments, the first reaction gas may be converted into the plasma, and the second reaction gas may be directly applied to the hardened photoresist pattern. Thus, the second reaction gas may not remove the polysilicon layer below the hardened photoresist pattern.

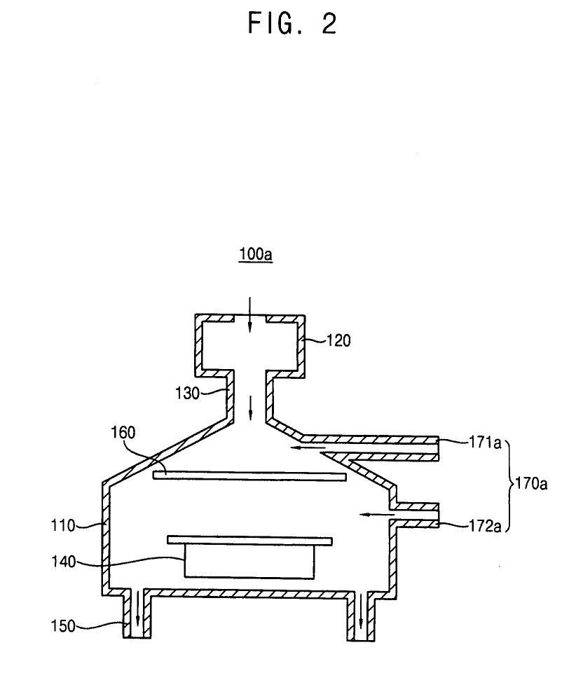

FIG. 2 illustrates a cross-sectional view of an ashing apparatus in accordance with another example embodiment.

An ashing apparatus 100a in accordance with this example embodiment may include elements substantially the same as those of the ashing apparatus 100 in FIG. 1, except for a gas line 170a. Thus, same reference numerals refer to the same elements and any further illustrations with respect to the same elements are omitted herein for brevity.

Referring to FIG. 2, the gas line 170a of the ashing apparatus 100a in accordance with this example embodiment may be connected to a sidewall of the ashing chamber 110. Particularly, the gas line 170a may include a first line 171a and a second line 172a. The first line 171a may be connected to an upper sidewall of the ashing chamber, which may be connected in a region higher than the baffle 160. The second line 172a may be connected to a lower sidewall of the ashing chamber 110, which may be connected in a region lower than the baffle 160.

Therefore, the second reaction gas may be introduced into an upper space over the baffle 160 through the first line 171a and a lower space under the baffle 160 through the second line 172a. Further, because the plasma and the second reaction gas may be chemically reacted with each other in the ashing chamber 110, the fluorine radicals may be generated in the ashing chamber 110.

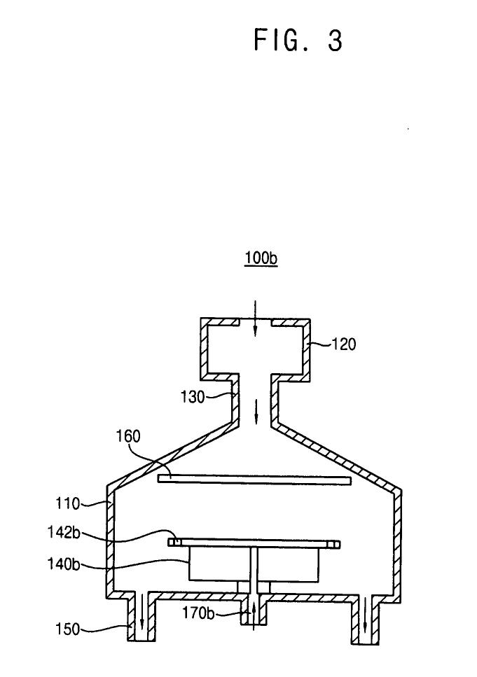

FIG. 3 illustrates a cross-sectional view of an ashing apparatus in accordance with another example embodiment.

An ashing apparatus 100b in accordance with this example embodiment may include elements substantially the same as those of the ashing apparatus 100 in FIG. 1, except for a gas line 170b and a chuck 140b. Thus, same reference numerals refer to the same elements and any further illustrations with respect to the same elements are omitted herein for brevity.

Referring to FIG. 3, the gas line 170b of the ashing apparatus 100b in accordance with this example embodiment may be connected to the chuck 140b. The chuck 140b may have a plurality of injection holes 142b for injecting the second reaction gas that may be supplied through the gas line 170b. In an example embodiment, the semiconductor substrate may be positioned on a central portion of the chuck 140b. Thus, to prevent the injection holes 142b from being blocked with the semiconductor substrate, the injection holes 142b may be arranged at an edge portion of the chuck 140b, for example.

Therefore, the second reaction gas may be chemically reacted with the plasma passing through the baffle 160 so that fluorine radicals may be generated in the ashing chamber 110.

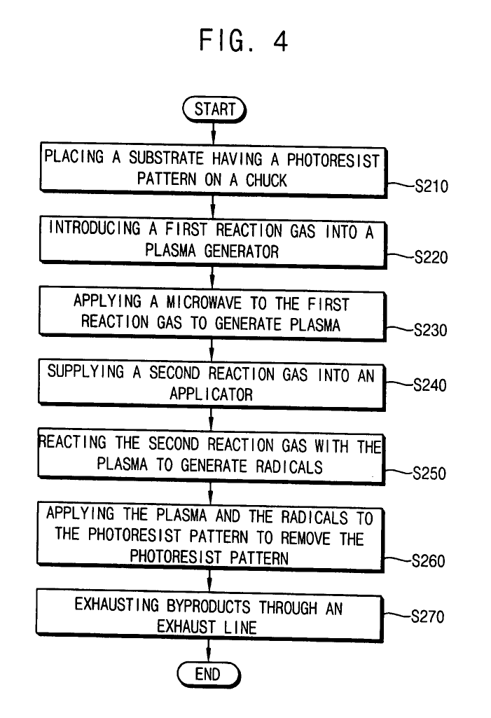

FIG. 4 illustrates a flow chart of a method of ashing a photoresist pattern using the apparatus in FIG. 1 in accordance with another example embodiment.

Referring to FIGS. 1 and 4, the semiconductor substrate on which the polysilicon layer and the hardened photoresist pattern owing to an ion implantation process may be sequentially formed may be loaded into the ashing chamber 110 (S210). The semiconductor substrate may then be placed on the chuck 140.

A first reaction gas including an oxygen gas and a nitrogen gas may then be introduced into the plasma generator 120 (S220). A microwave may then be applied to the first reaction gas to generate oxygen plasma and nitrogen plasma (S230).

A second reaction gas, e.g., a fluorine gas, may be introduced into the applicator 130 through the gas line 170 (S240). The second reaction gas and the plasma may then be chemically reacted with each other in the applicator 130 to generate fluorine radicals (S250).

The plasma and the fluorine radicals may pass through the baffle 160 and may then be distributed uniformly. The uniformly distributed plasma and fluorine radicals may be applied to the hardened photoresist pattern to remove the hardened photoresist pattern (S260). Because the fluorine radicals may have a low etching selectivity with respect to the polysilicon layer compared to that of the plasma, the fluorine radicals may not remove the polysilicon layer when removing the hardened photoresist pattern.

By-products generated in the ashing process may then be exhausted from the ashing chamber through the exhaust line 150 (S270).

Measuring an Etching Rate with Respect to a Polysilicon Layer

A polysilicon layer and a photoresist film may be sequentially formed on a semiconductor substrate. The photoresist film may be exposed and developed to form a photoresist pattern. Impurities may be implanted into the semiconductor substrate using the photoresist pattern as an ion implantation mask. An oxygen gas, a nitrogen gas and/or CHF₃ gas, for example, may be converted into plasma. The plasma may be applied to the photoresist pattern so as to remove the photoresist pattern. After completing the ashing process, thicknesses at thirteen positions on the polysilicon layer may be measured.

The measured thicknesses of the polysilicon layer may be shown in the following Table 1.

TABLE 1

| | Thickness (Å) | Thickness (Å) | Etching |
|---|---|---|---|
| Measured | before ashing | after ashing | rate |
| position | process | process | (Å/min) |
| 1 | 789.3 | 701.4 | 87.9 |
| 2 | 789.7 | 702.4 | 87.3 |
| 3 | 790.3 | 704.7 | 85.7 |
| 4 | 789.0 | 703.2 | 85.8 |
| 5 | 789.3 | 704.6 | 84.8 |
| 6 | 788.9 | 702.7 | 86.2 |
| 7 | 788.8 | 702.1 | 86.8 |
| 8 | 787.8 | 701.5 | 86.3 |
| 9 | 787.8 | 704.9 | 83.0 |
| 10 | 794.1 | 715.4 | 78.7 |
| 11 | 782.2 | 708.0 | 74.2 |
| 12 | 791.2 | 717.0 | 74.1 |
| 13 | 792.8 | 720.4 | 72.4 |
| Average | 789.3 | 706.8 | 82.5 |

As shown in Table 1, an average thickness of the polysilicon layer before the conventional ashing process may be approximately 789.3 Å. An average thickness of the polysilicon layer after the conventional ashing process may be approximately 706.8 Å, which may be lower than the average thickness before the ashing process of 789.3 Å. Thus, as shown in Table 1, an average etching rate of the fluorine plasma with respect to the polysilicon layer may be as high as approximately 82.5 Å/min.

In another example embodiment, a polysilicon layer and a photoresist film may be sequentially formed on a semiconductor substrate under conditions substantially the same as the above-mentioned conditions. The photoresist film may be exposed and developed to form a photoresist pattern. Impurities may be implanted into the semiconductor substrate using the photoresist pattern as an ion implantation mask. An oxygen gas and/or a nitrogen gas, for example, may be converted into oxygen plasma and nitrogen plasma. However, in this example embodiment, CHF₃ gas, for example, may not be converted into plasma. The CHF₃ gas may be reacted with the oxygen plasma to generate fluorine radicals. The oxygen plasma and the fluorine radicals may be applied to the photoresist pattern to remove the photoresist pattern. After completing the ashing process, thicknesses at thirteen positions on the polysilicon layer may be measured.

The measured thicknesses of the polysilicon layer may be shown in the following Table 2.

TABLE 2

| | Thickness (Å) | Thickness (Å) | Etching |
|---|---|---|---|
| Measured | before ashing | after ashing | rate |
| position | process | process | (Å/min) |
| 1 | 765.2 | 763.4 | 1.8 |
| 2 | 765.5 | 763.4 | 2.1 |
| 3 | 768.0 | 766.0 | 2.0 |
| 4 | 768.5 | 768.6 | 1.8 |
| 5 | 768.3 | 766.6 | 0.0 |
| 6 | 766.3 | 764.2 | 2.1 |
| 7 | 763.7 | 761.7 | 2.0 |
| 8 | 766.0 | 764.2 | 1.8 |
| 9 | 768.2 | 766.7 | 1.6 |
| 10 | 750.2 | 750.5 | 0.0 |
| 11 | 761.4 | 758.9 | 2.5 |
| 12 | 767.0 | 764.7 | 2.3 |
| 13 | 773.6 | 771.7 | 1.9 |
| Average | 765.5 | 763.9 | 1.7 |

As shown in Table 2, an average thickness of the polysilicon layer before the ashing process of the present invention may be approximately 765.5 Å. An average thickness of the polysilicon layer after the ashing process may be approximately 763.9 Å, slightly lower than 765.5 Å. Thus, an average etching rate of the fluorine plasma with respect to the polysilicon layer may be as low as approximately 1.7 Å/min.

As a result, when the hardened photoresist pattern is ashed using the method as discussed above, the polysilicon layer beneath the photoresist pattern may be scarcely removed.

According to example embodiments, only the oxygen gas may be converted into the oxygen plasma while the fluorine gas may not be converted into plasma. The oxygen plasma and the fluorine gas may be applied to the hardened photoresist pattern. Therefore, because the fluorine gas may have a low etching selectivity with respect to the polysilicon layer compared to that of the plasma, the polysilicon layer may not be removed and the hardened photoresist pattern may be removed or substantially removed. As a result, the thickness of the polysilicon layer may not be reduced after the ashing process so that an electrical reliability of the semiconductor device having the polysilicon layer may be still maintained.

Although the above example embodiments may describe utilizing gas as generating the plasma, one skilled in the art would appreciate that other fluids, such as, liquid, may be employed.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of ashing an object, comprising:
converting a first reaction fluid into plasma;
reacting the plasma with a second reaction fluid to generate radicals; and
ashing the object using the radicals and the plasma.

2. The method as claimed in claim 1, wherein the first reaction fluid is converted into the plasma using a microwave.

3. The method as claimed in claim 1, wherein converting the first reaction fluid into the plasma comprises converting a nitrogen gas into nitrogen plasma.

4. The method as claimed in claim 1, wherein the first reaction fluid includes an oxygen gas.

5. The method as claimed in claim 1, wherein the second reaction fluid includes a halogen gas.

6. The method as claimed in claim 5, wherein the second reaction fluid comprises at least one of a rifluoromethane (CHF₃) gas, a chlorine (Cl₂) gas, a nitrogen trifluoride (NF₃) gas and a hydrogen bromide (HBr) gas.

7. The method as claimed in claim 1, wherein the object is at least one of a hardened photoresist pattern, a nitride spacer and a metal polymer.

8. The method as claimed in claim 1, wherein:
the object is a hardened photoresist pattern,
the first reactive fluid includes an oxygen gas so as to convert oxygen gas into oxygen plasma, and
the second reactive fluid includes a fluorine gas so as to react oxygen plasma with the fluorine gas to generate fluorine radicals.

9. The method as claimed in claim 8, wherein the oxygen plasma is formed using a microwave.

10. The method as claimed in claim 8, wherein the oxygen plasma further comprises converting a nitrogen gas into nitrogen plasma.

11. An apparatus for ashing an object, comprising:
an ashing chamber that receives the object;
a plasma generator connected to the ashing chamber to convert a first reaction fluid into plasma; and
a fluid line that supplies a second reaction fluid into the ashing chamber, wherein the second reaction fluid is to be reacted with the plasma in the ashing chamber to generate radicals.

12. The apparatus as claimed in claim 11, further comprising a chuck placed in the ashing chamber to support the object.

13. The apparatus as claimed in claim 12, wherein the fluid line is connected to the chuck having a plurality of spraying holes for spraying the second reaction fluid supplied through the fluid line.

14. The apparatus as claimed in claim 11, further comprising a baffle placed over the object in the ashing chamber.

15. The apparatus as claimed in claim 14, wherein the fluid line is connected to a sidewall of the ashing chamber to supply the second reaction fluid into an upper spacer over the baffle and a lower spacer under the baffle.

16. The apparatus as claimed in claim 11, further comprising an applicator disposed between the plasma generator and the ashing chamber.

17. The apparatus as claimed in claim 16, wherein the fluid line is connected to the applicator.

18. The apparatus as claimed in claim 11, wherein the plasma generator comprises a microwave generator.

19. The apparatus as claimed in claim 11, wherein the first reaction fluid is at least one of an oxygen gas and a nitrogen gas, and the second reaction fluid is a rifluoromethane (CHF₃) gas.

20. The apparatus as claimed in claim 11, wherein the object comprises at least one of a hardened photoresist pattern, a nitride spacer and a metal polymer.
